(19) United States
(12) Patent Application Publication
(10) Pub. No.: US 2002/0089831 A1
(43) Pub. Date: Jul. 11, 2002

(54) Module with one side stacked memory

(76) Inventor: John A. Forthun, Glendora, CA (US)

Correspondence Address: STETINA BRUNDA GARRED & BRUCKER, 75 ENTERPRISE, SUITE 250, ALISO VIEJO, CA, 92656, US

(21) Appl. No.: 09/757,155

(22) Filed: Jan. 9, 2001

(51) Int. Cl. H05K 7/02

(52) U.S. Cl. 361/760

(57) ABSTRACT

A single sided module comprising a substrate which defines opposed first and second sides and includes a conductive pattern thereon. In addition to the substrate, the module comprises at least two chip stacks which are disposed on only the first side of the substrate and electrically connected to the conductive pattern. The chip stacks are placed into electrical communication with each other by the conductive pattern. The conductive pattern itself comprises a multiplicity of conductive pads which are disposed on only the first side of the substrate, and a multiplicity of conductive traces which electrically connect respective pairs of the conductive pads to each other. The conductive traces are themselves disposed on and extend along only the first side of the substrate, with the chip stacks being electrically connected to respective sets of the conductive pads.

### CROSS-REFERENCE TO RELATED APPLICATIONS

(Not Applicable)

### STATEMENT RE: FEDERALLY SPONSORED RESEARCH/DEVELOPMENT

(Not Applicable)

### BACKGROUND OF THE INVENTION

The present invention relates generally to electronic components, and more particularly to a module including a plurality of chip stacks which are in electrical communication with each other and disposed upon a common side of a substrate such as a printed circuit board thereby enhancing the speed and thus the performance of the module by limiting conductive trace lengths through the substrate and electrical discontinuities created by vias therewithin.

It has been recognized in the electronics industry that as the speed of memory is increasing, the electrical performance of memory modules is becoming increasingly critical. In addition to the need for optimal performance, there is an ever increasing need in the electronics industry for memory modules of greater capacity. The traditional approach taken in the prior art to achieve such increased capacity is through the use of dual in-line memory modules or DIMM modules, an example of which is shown as prior art in FIG. 1. Currently known DIMM modules typically comprise a substrate such as a printed circuit board which defines opposed, generally planar sides or faces. Disposed on each of the opposed sides of the substrate are a multiplicity of memory devices which are arranged in aligned pairs, i.e., a memory device on one side of the substrate is aligned with a corresponding memory device on the opposite side of the substrate. These memory devices typically comprise packaged integrated circuit chips (e.g., TSOP devices, BGA devices).

In the prior art DIMM module, each aligned pair of memory devices is typically electrically connected to each other and to the other aligned pairs of memory devices of the DIMM module. Though the prior art DIMM module provides increased memory capacity, it possesses certain deficiencies which detract from its overall utility. More particularly, due to the placement or positioning of the memory devices on each side of the substrate, the electrical connection of the various memory devices to each other necessitates the use of a complex array of conductive pads, conductive traces, and vias which are disposed upon and within the substrate. The electrical connection of the memory devices of the DIMM module to each other in parallel, which is often the case, requires that many of the conductive traces cross over each other thereby adding circuit layers, thus substantially increasing the overall length thereof throughout the DIMM module. Additionally, the vias themselves increase the risk of electrical discontinuities within the DIMM module. As will be recognized, the increased trace lengths and trace density on the substrate of the DIMM module compromises the signal integrity and performance thereof. As indicated above, as operational speeds increase, performance is now one of the most important objectives in memory module construction.

In addition to adversely impacting performance, the trace configuration of the prior art DIMM module increases the manufacturing costs associated therewith. Moreover, the positioning of the memory devices on each side of the substrate in the DIMM module creates difficulties in relation to testing due to the lack of availability of free areas on the substrate to provide for test pins or interface areas for test fixtures as are typically needed to allow for trouble shooting.

The present invention provides a novel and unique solution to the aforementioned deficiencies of prior art DIMM modules by providing a single sided module wherein high density chip stacks are disposed on only one common side of a substrate (e.g., a printed circuit board or PCB) and placed into electrical communication with each other via a conductive pattern including conductive traces of substantially reduced length as compared to those of prior art DIMM modules. Because the trace lengths of the electrical interconnects between the chip stacks is significantly less than in the prior art DIMM modules, the circuit performs better under high speed applications. Additionally, the use of the chip stacks on only one side of the board greatly simplifies trace routing thus reducing manufacturing costs, reduces the amount of vias needed in the board thereby minimizing or eliminating the risk of electrical discontinuities, reduces trace density, reduces the number of layers needed in the board, provides better/easier impedance control, and provides more exposed surface area (i.e., one side of the board is left bare) for the inclusion of test points. The module of the present invention is also significantly easier to assemble, thus further reducing the costs associated therewith. These, as well as other features of the present invention, will be discussed in more detail below.

### BRIEF SUMMARY OF THE INVENTION

In accordance with the present invention, there is provided a single sided module comprising a substrate which defines opposed, generally planar first and second sides or faces, and includes a conductive pattern. In addition to the substrate, the module comprises at least two chip stacks which are disposed on only the first side of the substrate and electrically connected to the conductive pattern. The chip stacks are placed into electrical communication with each other by the conductive pattern.

In the preferred embodiment, the conductive pattern itself comprises a multiplicity of conductive pads which are disposed on only the first side of the substrate. In addition to the conductive pads, the conductive pattern comprises a multiplicity of conductive traces which electrically connect respective pairs of the conductive pads to each other. The conductive traces themselves are preferably disposed on and extend along only the first side of the substrate. The chip stacks are themselves electrically connected to respective sets of the conductive pads. In the preferred embodiment, the substrate comprises a printed circuit board or PCB.

In the present module, each of the chip stacks preferably comprises at least two chip packages which are stacked upon and electrically connected to each other. Each of the chip packages itself preferably comprises a rectangularly configured frame which defines top and bottom surfaces and opposed pairs of longitudinal and lateral side sections. The frame includes a conductive array disposed thereon which itself preferably comprises first and second sets of frame pads which are disposed on respective ones of the top and bottom surfaces of the frame and extend along the longitudinal and lateral side sections thereof. The frame pads of the second set are electrically connected to respective ones of the frame pads of the first set.

In addition to the frame, each of the chip packages preferably comprises an integrated circuit chip which is electrically connected to the conductive array. More particularly, each integrated circuit chip preferably comprises a packaged chip (e.g., a TSOP packaged chip) having a body and a plurality of conductive leads protruding from the body. The conductive leads are electrically connected to respective ones of the pads of the first set such that the frame circumvents the body. The conductive arrays of the frames of the chip packages in the chip stack are electrically connected to each other, with the conductive array of the frame of the lowermost chip package of the chip stack being electrically connected to a corresponding set of the conductive pads of the conductive pattern.

Further in accordance with the present invention, there is provided a method of fabricating a single sided module. The method comprises the initial step of providing a substrate which defines opposed first and second sides and includes a conductive pattern. Thereafter, at least two chip stacks are disposed on only the first side of the substrate. The chip stacks are then electrically connected to the conductive patterns such that the chip stacks are placed into electrical communication with each other by the conductive pattern.

### BRIEF DESCRIPTION OF THE DRAWINGS

These, as well as other features of the present invention, will become more apparent upon reference to the drawings wherein:

FIG. 1 is a top perspective view of a prior art DIMM module;

FIG. 2 is a top perspective view of a single sided equivalent or higher density module constructed in accordance with the present invention;

FIG. 3 is cross-sectional view taken along line 3-3 of FIG. 2;

FIG. 4 is a exploded view of the present module illustrating the manner in which one of the chip stacks thereof is electrically connected to the conductive pattern of the substrate;

FIG. 5 is an exploded view of the chip stack shown in FIG. 4; and

FIG. 6 is an exploded view of one of the chip packages of the chip stack shown in FIG. 5.

### DETAILED DESCRIPTION OF THE INVENTION

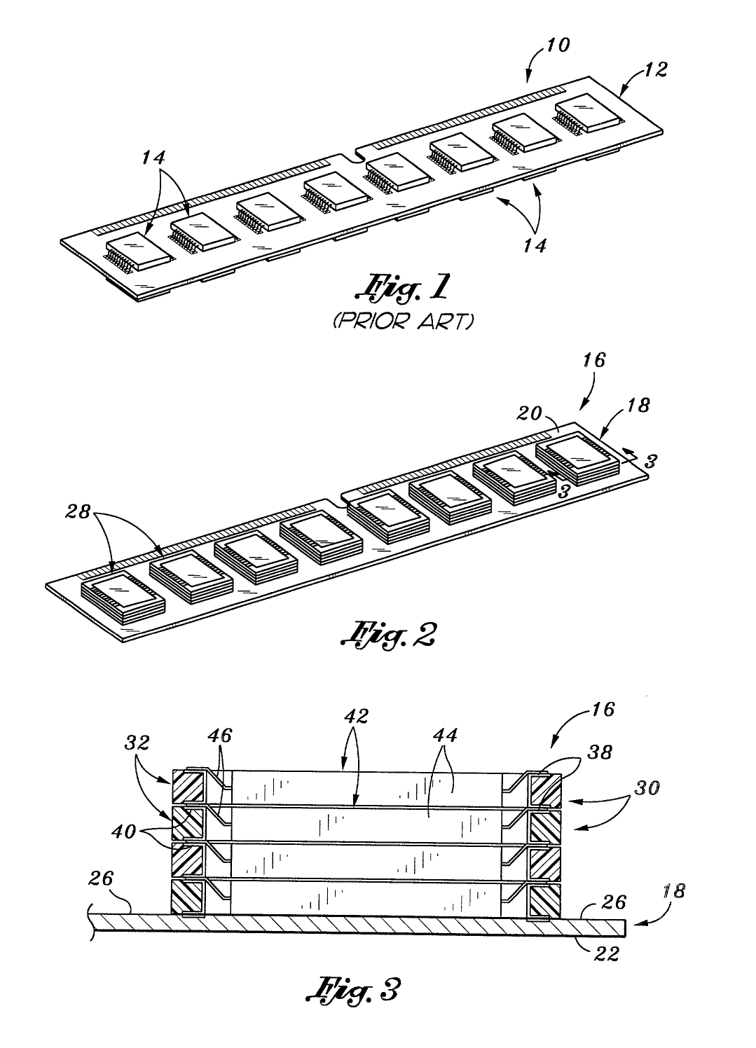

Referring now to the drawings wherein the showings are for purposes of illustrating a preferred embodiment of the present invention only, and not for purposes of limiting the same, FIG. 1 perspectively illustrates a prior art dual in-line, double sided memory module or DIMM 10. As indicated above, the DIMM 10 comprises a printed circuit board or PCB 12 which defines opposed, generally planar sides or faces. Disposed on each of the opposed sides of the PCB 12 are a multiplicity of memory devices 14. The memory devices 14 are arranged in aligned pairs, i.e., each memory device 14 disposed on one side of the PCB 12 is aligned with a corresponding memory device 14 on the opposite side of the PCB 12. As shown in FIG. 1, the memory devices 14 each comprise a single packaged integrated circuit chip (e.g., a TSOP device or a BGA device).

As also indicated above, in the prior art DIMM 10, the memory devices 14 of each aligned pair are typically connected to each other and to the other aligned pairs of memory devices 14 of the DIMM 10. Such electrical connection is facilitated through the use of a complex array of conductive pads, conductive traces, and vias which are disposed upon and within the substrate component of the PCB 12. The use of this complex array is necessitated in the DIMM 10 due to the placement or positioning of the memory devices 14 on each side of the PCB 12. Since the memory devices 14 of the DIMM 10 are often connected to each other in parallel, many of the conductive traces cross over each other, thus substantially increasing the overall length thereof throughout the DIMM 10. Additionally, the vias extending through the substrate component of the PCB 12 increase the risk of electrical discontinuities within the DIMM 10, which could have serious adverse effects on the performance thereof. The increased trace lengths, trace density and vias on the substrate component of the PCB 12 slows the performance speed of the DIMM 10 and compromises the signal integrity. In addition to slowing operational speed and thus adversely impacting performance, the trace configuration of the prior art DIMM 10 increases the manufacturing costs associated therewith. Moreover, the positioning of the memory devices 14 on each side of the PCB 12 creates difficulties in relation to the testing of the DIMM 10 due to the lack of availability of open or exposed areas on the PCB 12 to provide for test pins or interface regions for test fixtures.

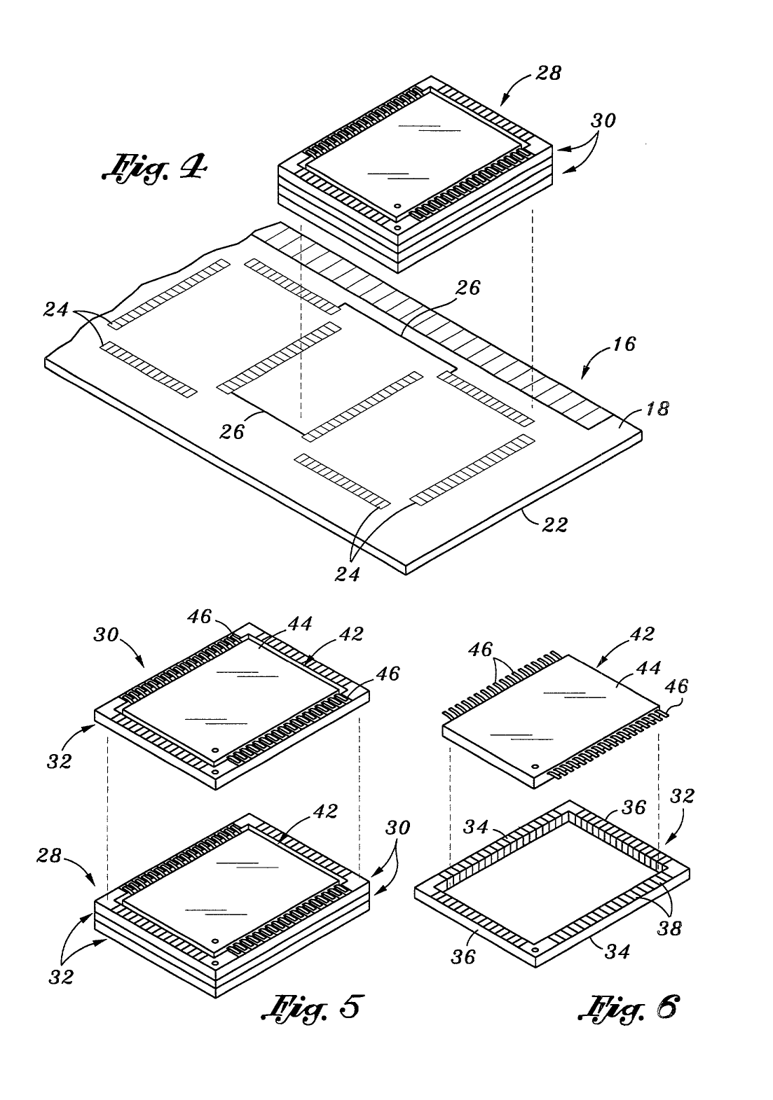

Referring now to FIG. 2, there is depicted a single sided module 16 constructed in accordance with the present invention. In the preferred embodiment, the module 16 comprises a substrate 18 which defines a generally planar first side 20 and an opposed, generally planar second side 22. Included on the substrate 18 is a conductive pattern which preferably comprises a multiplicity of conductive pads 24 which are disposed on only the first side 20 of the substrate 18. In addition to the conductive pads 24, the conductive pattern of the substrate 18 comprises a multiplicity of conductive traces 26 which are also disposed on and extend along only the first side 20 of the substrate 18. Exemplary conductive traces 26 are shown in FIGS. 3 and 4. The conductive traces 26 are used to electrically connect respective pairs of the conductive pads 24 to each other. The conductive pads and traces 24, 26 are each preferably fabricated from very thin copper through the use of conventional etching techniques. Additionally, the substrate 18 is typically fabricated from a conventional circuit board material. In the module 16 of the present invention, the substrate 18 (which includes the conductive pattern comprising the conductive pads and traces 24, 26) is preferably a printed circuit board or PCB. Those of ordinary skill in the art will recognize that as an alternative to being disposed upon the first side 20, the conductive traces 26 may extend internally within the substrate 18.

In addition to the substrate 18, the module 16 of the present invention comprises one or more chip stacks 28 which are disposed on only the first side 20 of the substrate 18. As will be described in more detail below, the chip stacks 28 are electrically connected to the conductive pattern of the substrate 18, and are placed into electrical communication with each other by the conductive pattern.

In the module 16, each of the chip stacks 28 preferably comprises at least two chip packages 30 which are arranged in a stacked configuration and electrically connected to each other. As seen in FIGS. 2 and 3, each of the chip stacks 28 is shown as including four (4) stacked chip packages 30. However, those of ordinary skill in the art will recognize that the present invention contemplates the use of chip stacks 28 which each include two (2) or more chip packages 30. Additionally, chip stacks 28 including differing numbers of chip packages 30 may be used in the same module 16.

Each chip package 30 preferably comprises a rectangularly configured frame 32 which includes an opposed pair of longitudinal side sections 34 and an opposed pair of lateral side sections 36. Disposed on the frame 32 is a conductive array which preferably comprises a first set of frame pads 38 disposed on the top surface of the frame 32 and a second set of frame pads 40 disposed on the bottom surface of the frame 32. The frame pads 38, 40 of the first and second sets preferably extend along the longitudinal and lateral side sections 34, 36 of the frame 32. Additionally, each of the frame pads 38 of the first set is preferably electrically connected to a respective one of the frame pads 40 of the second set. Such electrical connection may be facilitated by conductive traces which extend along the outer surface of the frame 32 or through the use of vias which extend therewithin.

In addition to the frame 32, each chip package comprises an integrated circuit chip 42 which is electrically connected to the conductive array on the frame 32. The integrated circuit chip 32 is preferably a packaged chip, such as a TSOP packaged chip. Though not shown, the integrated circuit chip 32 could also be a BGA device. Such packaged chip comprises a rectangularly configured body 44 defining opposed, generally planar top and bottom surfaces, and opposed pairs of longitudinal and lateral peripheral edge segments. Protruding from each of the longitudinal peripheral edge segments of the body 44 are a plurality of conductive leads 46 which, as seen in FIG. 3, each preferably have a gull-wing configuration. In each chip package 30, the electrical connection of the integrated circuit chip 42 to the frame 32 is preferably facilitated by electrically connecting the conductive leads 46 to respective ones of the frame pads 38 of the first set disposed on the top surface of the frame 32. Such electrical connection is typically facilitated through the use of solder.

In assembling each chip stack 28, the chip packages 30 are stacked upon each other such that the frame pads 40 of the second set of each chip package 30 are aligned with respective ones of the frame pads 38 of the first set of the chip package 30 immediately therebelow. Thus, as is most apparent from FIGS. 3 and 5, the conductive leads 46 of each integrated circuit chip 42 other than for the upper most integrated circuit chip 42 are disposed between respective aligned pairs of the frame pads 38, 40 of the first and second sets of adjacent frames 32. The frame pads 40 of the second set of the lower most chip package 30 in the chip stack 28 are preferably electrically connected to respective ones of the conductive pads 24 of the conductive pattern of the substrate 18. Thus, the conductive pads 24 are preferably arranged in rectangularly configured sets such that the chip stacks 28, and more particularly the second sets of frame pads 40 of the lower most chip packages 30 thereof, are placeable into alignment or registry therewith. In this respect, each of the chip stacks 28 is electrically connected to a corresponding rectangularly configured set of the conductive pads 24, with the conductive pads 24 of each rectangularly configured set being electrically connected to respective ones of the conductive pads 24 of the other rectangularly configured sets through the use of the conductive traces 26 as described above. As also indicated above, the conductive pads 24 are disposed on only the first side 20 of the substrate 18, thus resulting in the chip stacks 28 being disposed upon only the first side 20 when electrically connected to the conductive pattern of the substrate 18.

In each chip stack 28, the chip packages 30 are preferably electrically connected to each other through the use of a solder reflow technique, with such technique also preferably being used to facilitate the electrical connection of the chip stacks 28 to respective sets of the conductive pads 24. A more detailed discussion of the structure and manner of assembly of each of the chip stacks 28 is found in Applicant's U.S. Pat. No. 5,869,353, the disclosure of which is incorporated herein by reference.

Those of ordinary skill in the art will recognize that the chip stacks 28 as described above are exemplary only, and that different types of chip stacks may be used in the module 16 of the present invention as an alternative to the chip stacks 28. Additionally, such alternative chip stacks may not necessarily require the arrangement of the conductive pads 24 on the first side 20 of the substrate 18 in rectangularly configured sets. For example, chip stacks may be used which have frames including frame pads extending along only the longitudinal or lateral side sections thereof, thus requiring that the conductive pads 24 of the corresponding set be provided in spaced, generally parallel rows rather than in a rectangular array or pattern. Irrespective of the precise configuration of the chip stack 28, the present invention involves the placement of such chip stacks 28 on only the first side 20 of the substrate 18. It is contemplated that the number of chip packages 30 included in each chip stack 28 will be sufficient to provide a density commensurate to that achieved by each aligned pair of memory devices 14 of the prior art DIMM 10. The chip stacks 28 provide for the parallel connection of the integrated circuit chips 42 thereof to each other in a space efficient manner.

As indicated above, typical high density circuit assemblies employ the use of both sides of the printed circuit board (PCB) or substrate to mount and interconnect components. The problem with this approach is that when assemblies become especially dense, routing becomes difficult. Circuit board layers are increased which increases the cost of fabricating the PCB/substrate. Additionally, the signal integrity of the routed traces are compromised due to the increased number of vias, branching of circuit lines (stubs), and difficulty of controlling trace line impedance. Test points are often sacrificed since there is no exposed PCB area available to place such test points. Though the prior art DIMM 10 may be half populated for lower density configurations, this leaves unnecessary and unused circuitry on the PCB 12 which compromises the signal integrity and possible performance that could be achieved if such circuitry were not included thereon. In this respect, optimized modules would remove this unused circuitry, and use only the connections on a single side of the PCB for building an optimized, highest performance, lower density module.

In the present invention, which is well suited for systems that have components having a high degree of interconnect in parallel, a more electrically optimized and lower costing assembly is achieved by stacking these components and placing all of them on one side of the PCB or substrate 18. The present invention recognizes that an optimized module having the same density as the DIMM 10 may be achieved by moving the components on one side to the other side through the use of stacking. The single sided substrate 18 of the present module 16 could be designed to handle both densities, with a lower density being achieved using non-stacked components and the normal double-sided DIMM module density being achieved using stacks. The one-sided module 16 of the present invention provides more area on the substrate 18 where additional test points can be added along with closely placed by-pass capacitors. In this respect, placing components on one side opens up the area on the other side of the substrate 18 to place test points as well as carefully placed by-pass capacitors. By-pass capacitors need to be as close to an integrated circuit's power and ground pins as possible, with the free side of the substrate 18 allowing for such very close placement.

As the speed of memories and of system requirements is always increasing, connecting components together on the DIMM 10 and then connecting DIMM's 10 together on a system can eat away at the performance that is achievable. As explained above, an optimal design is achieved by the module 16 of the present invention wherein the components are placed on one side of the PCB or substrate 18. Besides improving the circuit trace routing with more direct routing, less vias and stubs, and better controlled circuit impedance, assembly of the module 16 is easier. Only one pass through an oven during the manufacturing process is required which prevents most parts from seeing an additional pass through the oven, which in turn results in better long term reliability. Additionally, throughput is higher, with the manufacturing process being more simple.

Thus, the present invention essentially takes a double sided surface mounted assembly, moves all of the components to one side of the PCB or substrate, and stacks the components where possible. Thus, the present invention makes full use of the electrical advantage of the short interconnect of the stacked components as compared to components on opposite sides of a PCB or substrate, as well as the advantages of reduced routing complexities with more direct routing, less branching (stubs) and less vias (electrical discontinuities). Additionally, the reduced routing density achieved with the present invention allows space to add ground shielding, wider traces, and spacing between traces for better impedance control and electrical performance (crosstalk, signal noise, current capacity).

In sum, the module 16 of the present invention, wherein the high density chip stacks 28 are disposed on only the first side 20 of the substrate 18, provides numerous advantages over the prior art DIMM 10. In this respect, the conductive traces 26 of the conductive pattern of the substrate 18 which are used to place the chip stacks 28 into electrical communication with each other are substantially more direct with reduced length and less branching or electrical stubs as compared to those of the prior art DIMM 10. Because of these improvements, the module 16 of the present invention performs better under high speed applications. Additionally, the inclusion of the chip stacks 28 on only the first side 20 of the substrate 18 greatly simplifies trace routing thus reducing manufacturing costs, reduces or eliminates the amount of vias needed in the substrate 18 thus minimizing the risk of electrical discontinuities, reduces trace density on the substrate 18, reduces the number of layers need in the substrate 18, provides better/easier impedance control, and provides more surface area (i.e., the second side 22 of the substrate 18 is left bare) for the inclusion of test points and optimally placed by-pass capacitors. The module 16 of the present invention is also significantly easier to assemble, thus further reducing the costs associated therewith.

Additional modifications and improvements of the present invention may also be apparent to those of ordinary skill in the art. Thus, the particular combination of parts and steps described and illustrated herein is intended to represent only one embodiment of the present invention, and is not intended to serve as limitations of alternative devices and methods within the spirt and scope of the invention.

1. A single sided module comprising:
a substrate which defines opposed first and second sides and includes a conductive pattern; and
at least two chip stacks disposed on only the first side of the substrate and electrically connected to the conductive pattern;
the chip stacks being placed into electrical communication with each other by the conductive pattern.

2. The module of claim 1 wherein the conductive pattern comprises:
a multiplicity of conductive pads disposed on only the first side of the substrate; and
a multiplicity of conductive traces electrically connecting respective pairs of the conductive pads to each other;
the chip stacks being electrically connected to respective sets of the conductive pads.

3. The module of claim 2 wherein the conductive traces are disposed on and extend along only the first side of the substrate.

4. The module of claim 2 wherein the substrate is a printed circuit board.

5. The module of claim 2 wherein each of the chip stacks comprises:
at least two chip packages, each of the chip packages comprising:
a frame having a conductive array disposed thereon; and
an integrated circuit chip electrically connected to the conductive array;
the conductive arrays of the frames of the chip packages being electrically connected to each other, with the conductive array of the frame of one of the chip packages being electrically connected to a respective set of the conductive pads of the conductive pattern.

6. The module of claim 5 wherein:
the frame defines opposed top and bottom surfaces; and
the conductive array comprises:
a first set of frame pads disposed on the top surface of the frame; and
a second set of frame pads disposed on the bottom surface of the frame and electrically connected to respective ones of the frame pads of the first set.

7. The module of claim 6 wherein:
the frame has a generally rectangular configuration defining opposed pairs of longitudinal and lateral side sections;
the first and second sets of frame pads extend along the longitudinal and lateral side sections of the frame;
the integrated circuit chip comprises a packaged chip having a body and a plurality of conductive leads protruding from the body; and
the conductive leads are electrically connected to respective ones of the pads of the first set such that the frame circumvents the body.

8. The chip stack of claim 7 wherein the packaged chip comprises a TSOP packaged chip.

9. A method of fabricating a single sided module comprising the steps of:
(a) providing a substrate which defines opposed first and second sides and includes a conductive pattern;
(b) disposing at least two chip stacks on only the first side of the substrate; and
(c) electrically connecting the chip stacks to the conductive pattern such that the chip stacks are placed into electrical communication with each other by the conductive pattern.

10. The method of claim 9 wherein:
step (a) comprises forming the conductive pattern to include a multiplicity of conductive pads which are disposed on only the first side of the substrate; and
step (c) comprises electrically connecting the chip stacks to respective sets of the conductive pads.

11. The method of claim 10 wherein:
step (a) further comprises forming the conductive pattern to include a multiplicity of conductive traces which electrically connect respective pairs of the conductive pads to each other and are disposed on and extend along only the first side of the substrate.
